(19) United States
(12) Patent Application Publication
(10) Pub. No.: US 2017/0154895 A1
(43) Pub. Date: Jun. 1, 2017

(54) Three-Dimensional Semiconductor Device and Manufacturing Method Therefor

(71) Applicant: Institute of Microelectronics, Chinese Academy of Sciences, Chaoyang, District, Beijing (CN)

(72) Inventor: Zongliang HUO, Zhongguancun, Haidian District - Bejing (CN)

(21) Appl. No.: 15/321,037

(22) PCT Filed: Jul. 10, 2014
(86) PCT No.: PCT/CN2014/081923

§ 371 Date: Dec. 21, 2016

(30) Foreign Application Priority Data
Jun. 23, 2014 (CN) 201410284777.5

(51) Int. Cl. H01L 27/11582; H01L 21/28; H01L 27/1157

(52) U.S. Cl. CPC H01L 27/11582; H01L 27/1157; H01L 21/28282

(57) ABSTRACT

A three-dimensional semiconductor device, comprising a plurality of memory cell transistors and a plurality of select transistors at least partially overlapped in the vertical direction, wherein each select transistor comprises a first drain, an active region and a common source formed in the substrate, distributed along the vertical direction, as well as a metal gate distributed around the active region; wherein each memory cell transistor comprises a channel layer distributed perpendicularly to the substrate surface, a plurality of inter-layer insulating layers and a plurality of gate stack structures alternately stacked along the sidewalls of said channel layer, a second drain located on top of said channel layer; wherein said channel layer and said the first drain are electrically connected. In accordance with the three-dimensional semiconductor memory device and manufacturing method of the present invention, the multi-gate MOSFET is formed beneath the stack structure of the memory cell string including vertical channel to serve as the select transistor, this can improve the control characteristics of the gate threshold voltage, reduce the off-state leakage current, prevent the substrate from over-etching, and effectively improve the reliability of the device.

This application is a National Phase application of, and claims priority to, PCT Application No. PCT/CN2014/081923, filed on Jul. 10, 2014, entitled “3-D Semiconductor Device and Manufacturing Method thereof”, which claimed priority to Chinese Application No. 201410284777.5, filed on Jun. 23, 2014. Both the PCT Application and Chinese Application are incorporated herein by reference in their entireties.

### TECHNICAL FIELD

The present invention relates to a semiconductor device and manufacturing method thereof, particularly to a three-dimensional semiconductor memory device and manufacturing method thereof.

BACKGROUND TECHNIQUE

In order to improve the density of the memory device, the industry has worked extensively at developing a method for reducing the size of a two-dimensional arrangement of memory cells. As the size of the memory cells of the two-dimensional (2D) memory devices continues to shrink, signal conflict and interference will significantly increase, so that it is difficult to perform operation of multi-level cell (MLC). In order to overcome the limitations of 2D memory device, the industry has developed a memory device having a three-dimensional (3D) structure, to improve the integration density by way of three-dimensionally arranging the memory cells on the substrate.

One of the common 3D memory device structures used in current industry is terabit cell array transistor (TCAT). Specifically, a multilayer laminated structure (e.g., a plurality of ONO structures composed of alternating oxide and nitride layers) may firstly deposited on the substrate; by an anisotropic etching process for etching the multilayer laminated structure on the substrate, a plurality of channel through-holes distributed along the word line (WL) of memory cell extending direction and perpendicular to the substrate surface are formed (may extend through to the substrate surface or with a certain over-etch); a plurality of pillar-shaped channels are formed in the channel through-holes by depositing polysilicon material; the multilayer laminated structure is etched along the WL direction to form a plurality of trenched through to the substrate, exposing the multilayer stack surrounding the pillar-shaped channels; optionally, a first type material in the stack is removed laterally by wet etching, forming a plurality of lateral recesses with a certain depth on sidewalls of the first type material, then the lateral recesses are filled with materials having charge storage capability for using as floating gate; a second type of material in the stack is removed by wet etching (e.g., using hot phosphoric acid to remove silicon nitride, or HF to remove silicon oxide), leaving a plurality of projecting structures lateral distributed around the pillar-shaped channels; a gate dielectric layer (such as high-k dielectric materials) and a gate conductive layer (Ti, W, Cu, Mo, etc.) are deposited on the side walls of the projecting structures in the trenches to form a gate stack; a portion of the gate stack out of the lateral plane of the projecting structures is removed by vertical anisotropic etching until the gate dielectric layer on the side of the projecting structures is exposed; the laminated structure is etched to form a plurality of source/drain contacts, and rear end of the manufacturing processes are completed. Here, a portion of projecting structures of the laminated structure leaving on the sidewall of pillar-shaped channels forms a plurality of spacers between the gate electrodes, leaving the gate stacks sandwiched between the spacers as control electrodes. When a voltage is applied to the gates, the fringe field of the gate will enable a plurality of source and drain regions to be formed on sidewalls of pillar-shaped channels made of e.g. polysilicon material, thereby constituting a gate array composed of a plurality of MOSFETs series-parallel coupled to record the stored logic states. Wherein, in order to extract the signal of a plurality of MOSFETs series-parallel coupled in the cell regions, the drain region are formed by deposition filling the top of the pillar-shaped channel with polycrystalline silicon material, and the metal contact plugs electrically connected to the drain regions are also formed to form further electrical connection with the bit-line (BL) thereon. In addition, a common source region containing metal silicide contacts is formed in the substrate between a plurality of vertical pillar-shaped channels. Under the conductive condition of the unit, the current flows from the common source region to the vertical channel region around, upwardly passes through a plurality of induced sources and drain regions in the vertical channels under the influence of the control voltage applied on the control gates (connected to the word lines), and further flows to the bit-line thereon through the drain regions on top of the channels.

The TCAT device structure has advantages of body-erase (adjusting the control gate can cause the electric potential change of the induced source and drain regions and the floating gate, which can be erased in its entirety) and metal gate (it can be more convenient to adjust the transistor threshold through controlling the work function of the metal material), however, since the select transistor (located above or below the memory transistor cell string) and the storage unit are formed by one cycle of etching and deposition-shaping, it is difficult to accurately adjust the threshold of the select transistor, thereby it is difficult to meet the application requirements of some high driving-performance. Furthermore, this structure is facing an over-etching problem during the formation process of a vertical channel and a common source, resulting in the deterioration of the device reliability. Another common device structure is NAND configuration using the BiCS (bit cost scalable) for example, the integration density is improved by arranging the memory cell on the substrate three-dimensionally. Wherein the channel layer is vertically erected on the substrate, the gate is divided into three parts, namely a lower select gate layer, a middle control gate layer and an upper select gate layer, the crosstalk between signals can be reduced by distributing the gate signals into three groups of the gate electrodes. Specifically, the devices on top and bottom layers are used as select transistors—vertical MOSFET with larger gate height/thickness, the gate dielectric layer is a single layer of conventional high-k material; the device at the middle layer is used as a memory cell string with smaller gate height/thickness, the gate dielectric layer has stack structure composed of a tunneling layer, a storage layer and a barrier layer.

The specific manufacturing processes of the above-described device generally include, depositing the lower select gate electrode layer on a silicon substrate, etching the lower select gate electrode layer to form trenches through to the substrate for further deposition of the lower portion of channel layer and the lead-out contact of the lower gate electrode, depositing the control gate layer over the lower select gate electrode layer, etching the control gate layer to form an intermediate channel region used for memory cell region and to create the lead-out contact for the middle control gate electrode, etching to form the control gate, dividing the whole device into a plurality of regions according to the word- and bit-line dividing requirements, depositing the upper select gate layer over the control gate layer and etching it, depositing to form the upper channel and the upper lead-out contact, then completing the device fabrication through the subsequent processes. In this process, the most critical etching step is merely the lithography of memory channel region and lead-out contact at the intermediate layer, which directly determines the integration density and signal anti jamming capability of the whole device.

However, although the BiCS structure can use the control gate threshold through the stacked placement of the storage array and select transistors respectively, it can only do erasing by gate-induced drain-leaked current (GIRL), unable to do body-erase, which results in low read-write efficiency.

### SUMMARY OF THE INVENTION

From the above, an object of the invention lies to overcome the above-mentioned technical difficulties, and propose an innovative 3-D semiconductor memory device manufacturing method.

To this end, the present invention provides a three-dimensional semiconductor device, comprising a plurality of memory cell transistors and a plurality of select transistors at least partially overlapped in the vertical direction, wherein each select transistor comprises a first drain, an active region and a common source formed in the substrate, distributed along the vertical direction, as well as a metal gate distributed around the active region; wherein each memory cell transistor comprises a channel layer distributed perpendicularly to the substrate surface, a plurality of inter-layer insulating layers and a plurality of gate stack structures alternately stacked along the sidewalls of said channel layer, a second drain located on top of said channel layer; wherein said channel layer and said the first drain are electrically connected.

Wherein, said metal gate is of multi-gate structure or annular gate structure. Wherein, the transverse dimension of said first drain is greater than or equal to that of said channel layer.

Wherein, each select transistor includes a gate insulating layer, said gate insulating layer surrounds the bottom and sidewalls of said metal gate. Wherein, each of the plurality of gate stack structures comprises a gate dielectric layer composed of a tunneling layer, a storage layer and a barrier layer.

The present invention also discloses a method of manufacturing a three-dimensional semiconductor device, comprising the steps of: forming an active region of the select transistor on a substrate; forming a metal gate of select transistor around the active region; forming a stack structure of the plurality of first material layers and the second material layers on the select transistor; etching the stack structure to form a plurality of vertical trenches; forming a channel layer of a memory cell transistor in each trench; selectively etching the second material layers, leaving a plurality of lateral recesses between the first material layers; forming a plurality of gate stack structures in the plurality of lateral recesses.

Wherein, the steps of forming the active region comprise:

a) Etching the substrate to form a plurality of vertically distributed active regions; or
b) Forming a mask stack structure composed of the first mask layer and the second mask layer on the substrate, etching the mask stack structure to form through-holes, forming active regions in the through-holes by deposition.

Wherein, further comprise:

a1) After forming a metal gate, forming an inter-layer dielectric layer on the substrate, etching the inter-layer dielectric layer to form an opening exposing the active region, forming a first drain in the opening; or
b1) before forming a metal gate, forming an opening exposing the active region on top of the mask stack structure, forming a first drain in the opening.

Wherein, the transverse dimension of said first drain is greater than or equal to that of said openings exposing the active regions.

Wherein, each of the plurality of gate stack structure comprises a gate dielectric layer composed of a tunneling layer, a storage layer and a barrier layer.

In accordance with the three-dimensional semiconductor memory device and manufacturing method of the present invention, the multi-gate MOSFET is formed beneath the stack structure of the memory cell string with vertical channel to serve as the select transistor, this can improve the control characteristics of the gate threshold voltage, reduce the off-state leakage current, prevent the substrate from over-etching, and effectively improve the reliability of the device.

### BRIEF DESCRIPTION OF THE DRAWINGS

Referring to the following drawings, the technical solutions of the present invention are described in detail in which:

FIGS. 1 to 16 are cross-sectional views of the various steps of the 3-D semiconductor device manufacturing method in accordance with the first embodiment of the present invention;

FIGS. 17 to 25 are cross-sectional views of the various steps of the 3-D semiconductor device manufacturing method in accordance with the second embodiment of the present invention;

### DETAILED DESCRIPTION

The features and technical effects of the present invention will be described in detail with reference to the drawings and schematic embodiments, disclosing semiconductor memory device and manufacturing method thereof for effectively improving gate control performance and the reliability of the device. It should be noted that the similar reference numbers denote the similar structure. The terms used in the present invention like “first”, “second”, “up/upon”, “down/low/beneath/under” etc. can be used in denoting various device structures, and do not indicate the relationship in space, sequence or hierarchy of the device structures unless specially illuminated these terms, if not stated otherwise.

FIGS. 1 to 16 are cross-sectional views of the various steps of the methods of forming multi-gate select transistor based on the gate-first process and forming memory transistor string thereon in accordance with the first embodiment of the present invention.

As shown in FIG. 1, substrate 1 is provided. The material of substrate 1 may comprise a bulk silicon (bulk Si), bulk germanium (bulk Ge), silicon-on-insulator (SOI), germanium-on-insulator (GeOI), or other compound semiconductor substrate, e.g., SiGe, SiC, GaN, GaAs, InP and the like, and combinations of these substances. For compatibility with the existing IC fabrication process, the substrate 1 is preferably a substrate containing silicon material, e.g., Si, SOI, SiGe, Si:C and the like. Preferably, doping is performed on the substrate 1 to form n- or p-type well region (not shown), to serve as a select transistor well region including a channel region.

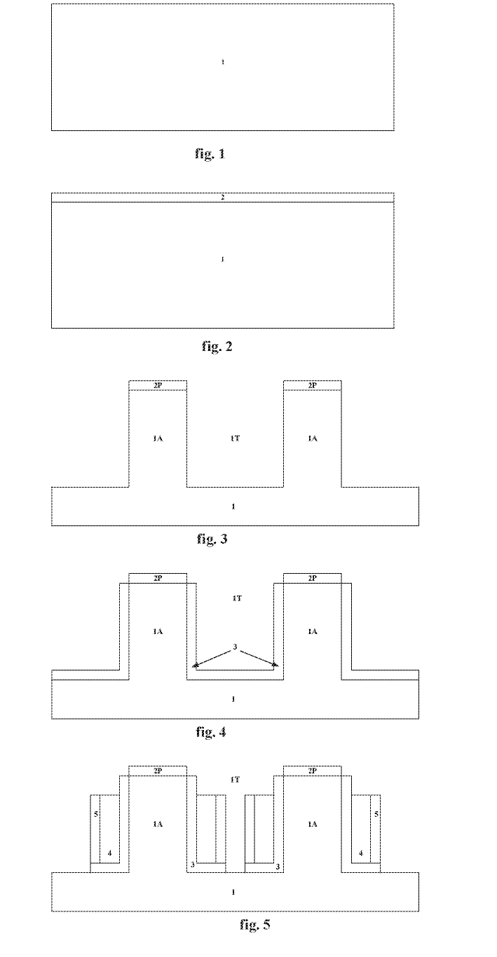

Optionally, as shown in FIG. 2, a hard mask layer 2 is formed on the substrate 1. Using PECVD, LPCVD, HDPCVD, MOCVD, MBE, ALD, thermal oxidation, evaporation, sputtering, and other processes, the hard mask layer 2 is formed on the top of substrate 1, the material of the hard mask layer 2 is selected from materials having a relatively greater etching selectivity ratio to substrate 1, such as silicon nitride, silicon oxide, silicon oxynitride, amorphous carbon and so on (e.g., an etching selectivity ratio greater than 5:1, or even greater than 10:1).

As shown in FIG. 3, using the hard mask layer 2 as a mask, the substrate 1 is etched to form active regions 1A. Optionally, the hard mask layer 2 is coated by a photoresist layer (not shown), and the photoresist pattern is formed through exposure and development process. Preferably, using the photoresist pattern as the mask, and through anisotropic dry etching process such as Ar plasma dry etching or reactive ion etching (RIE) containing C- or F-based etching gas, the hard mask layer 2 is etched to form hard mask pattern 2P firstly, and then adjust the etching process parameters to enable the substrate 1 to be more fast etched. A plurality of active regions 1A are formed by etching to serve as the bottom active region of multi-gate select transistors, a plurality of recesses 1T are located between the active regions 1A. The active regions 1A comprise a plurality of the pillar-shaped structure projecting perpendicularly from the top surface of the substrate 1, of which the cross-sectional shape may be various geometric shapes selected from rectangular, square, diamond, circular, semi-circular, elliptical, triangular, pentagonal, hexagonal, octagonal, etc.

As shown in FIG. 4, the first gate insulating layer 3 is formed on the top of the substrate 1 and on sidewalls of the active regions 1A. Through process such as PECVD, LPCVD, HDPCVD, MOCVD, MBE, ALD, thermal oxidation, etc., dielectric material selected from silicon nitride, silicon oxide, silicon oxynitride or other high-k materials is deposited to serve as the gate insulating layer 3 of multi-gate select transistor. Wherein the high-k materials include but are not limited to nitride (such as SiN, AlN, TiN), metal oxides (mainly subgroup and lanthanide metal element oxides, such as MgO, Al2O3, Ta2O5, TiO2, ZnO, ZrO2, HfO2, CeO2, Y2O3, La2O3)), nitrogen oxides (e.g., HfSiON), perovskite phase oxides (e.g. PbZrxTi1-xO3 (PZT), BaxSr1-xTiO3 (BST)), etc.

As shown in FIG. 5, a plurality of the first gate electrodes 4 of the select transistors are formed on sidewalls of the active regions 1A, and the sidewalls 5 are formed on sidewalls of the first gate electrodes 4. First, the gate insulating layer 3 is etched, leaving a first vertical part on sidewalls of the active regions 1A and a shorter second horizontal part on the top of the substrate 1. Using processes such as PECVD, HDPCVD, MBE, ALD, sputtering, electroplating, chemical plating, etc., a plurality of the first gate electrodes 4 made of metal materials are formed at the gate insulating layer 3, i.e., the metal gate electrodes 4 are formed on the side of the first portion of the gate insulating layer 3 and also on the top of the second portion thereof. The materials of the metal gate electrodes 4 may include metal elements such as Co, Ni, Cu, Al, Pd, Pt, Ru, Re, Mo, Ta, Ti, Hf, Zr, W, Ir, Eu, Nd, Er, La and the others, or alloys and nitrides of these metals, besides, may also be further doped with C, F, N, O, B, P, As and other elements in order to adjust the work function to precisely control the threshold voltage of the select transistor. Nitride barrier layers (not shown) are preferably formed between the metal gate electrodes 4 and the gate insulating layer 3 by PVD, CVD, ALD and other conventional processes, the material of barrier layers is MxNy, MxSiyNz, MxAlyNz, MaAlxSiyNz, wherein the M is Ta, Ti, Hf, Zr, Mo, W, or other elements. Thereafter, the insulating material is deposited on the side of the gates 4 firstly, and then gate sidewalls 5 are formed by isotropic etching. As shown in FIG. 5, the gates 4 are formed at least on both sides of the active regions 1A, i.e., the device may also be double gate structure, however, in other embodiments, the gates 4 can actually surround the active regions 1A to form a ring gate structure, or can be a plurality of gates distributed surrounding the active regions 1A (e.g. the number thereof can be 3, 4, 6, 8, and etc.), this can make the electric field distribution in the active regions 1A to be controlled more precisely, thereby improving the performance of select transistor. Besides, the height of the metal gates 4 is lower than the active regions 1A as shown in FIG. 5, so as to facilitate the subsequent formation of the drain region of the select transistor. Naturally, the height of the metal gates 4 can also be equal to that of the active regions 1A.

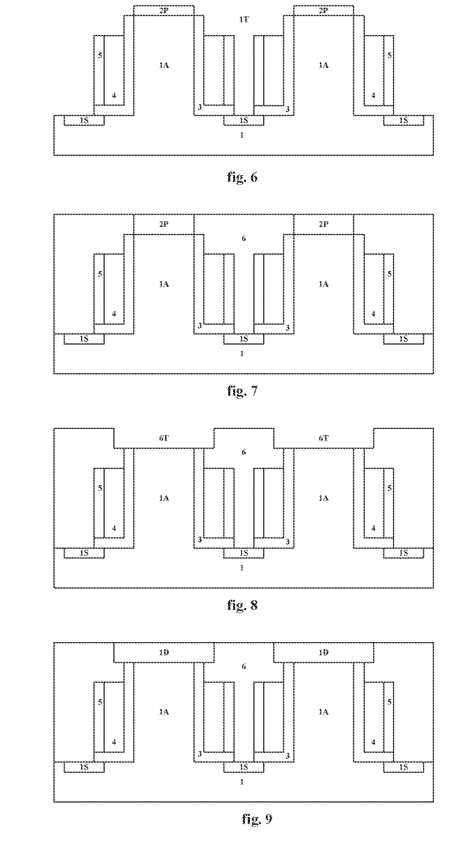

As shown in FIG. 6, the common source regions 1S are formed in the substrate 1 exposed from the recess 1T. Source regions 1S can be formed by doping with ionic implanted, and preferably by forming metal silicides (not shown) on the surface in order to reduce the contact resistance. The metal silicides are such as NiSi2-y, Ni1-xPtxSi2-y, CoSi2-y or Ni1-xCoxSi2-y, wherein the x is greater than 0 and less than 1, and the y is greater than or equal to 0 and less than 1. In this process, since the subsequent formation of the vertical channel of the memory transistor string is on top of the drain above the active region 1A, the substrate is protected by the drain, meanwhile the substrate is protected by the hard mask layer 2 in process of etching the active region as previously shown in FIG. 3, therefore there is no problem of over-etching the substrate 1, leading to the reduction of surface defects and the improvement of the channel region performance, thereby improving the device reliability of the select transistor and the memory transistor.

As shown in FIG. 7, a first interlayer dielectric layer (ILD) 6 is formed on top of the device. Using processes such as spin coating, printing, spraying and so on, ILD6 made of low-k materials is formed, wherein the low-k materials include but are not limited to organic low-k material (e.g. an aromatic group or a polycyclic organic polymer), inorganic low-k material (e.g. amorphous CN thin film, polycrystalline boron-nitrogen film, fluorinated silicate glass, BSG, PSG, BPSG), porous low-k material (such as dimethyl silicone three siloxane (SSQ) based porous low-k material, porous silica, porous SiOCH, mixed C silica, F-doped amorphous porous carbon, porous diamond, porous organic polymer). Preferably, ILD6 is planarized through the process such as CMP, etch-back and so on, until the hard mask pattern 2P is exposed.

As shown in FIG. 8, the hard mask pattern 2P is removed, leaving the trenches 6T in ILD6. For different materials of the hard mask layer pattern 2P, a suitable wet etching solution can be chosen, such as hot phosphoric acid for removing 2P made of silicon nitride material, or a suitable dry etching processes can be chosen, such as oxygen plasma dry etching for removing 2P made of the amorphous carbon material (this method can effectively improve the cleanliness of the etching removal, avoiding the residue of the film 2P, followed by using HF-based etching solution to remove the native silicon oxide film). Preferably, the lateral etching rate is increased or an appropriate etching mask is chosen in order to make the width of the trenches 6T larger than that of the active regions 1A. Preferably, the transverse width of the trenches 6T is greater than at least 1.5 times the transverse width of the vertical channel layer thereon, and preferably 2 to 4 times.

As shown in FIG. 9, the drain regions 1D of the select transistor are formed by filling the trenches 6T. Using epitaxial process such as MBE, ALD, etc., or deposition process such as PECVD, HDPCVD, MOCVD, etc., the trenches 6T are filled with semiconductor material to form the drain regions 1D, the material can be the same as or similar to that of the active regions 1A and substrate 1, for example, Si (polycrystalline or monocrystalline), SiGe, Si:C. Preferably, using in-situ doping for both deposition and epitaxial process, i.e. introducing raw gases such as SiH4 gas and also the gases containing dopant atoms such as the borane, phosphine, etc., thereby forming a plurality of doped n+ or p+ type drain regions 1D. Besides, after the deposition is completed, other process such as the ion implantation process can also be used to form the doped drain regions. As shown in FIG. 8, the width of each trench 6T is greater than that of the active region 1A, so that the width of each drain region 1D is larger than that of the active region 1A, this can increase the drain region area of the selection transistor, avoid the vertical channel region dislocation and the mismatch issues between the memory transistor and the select transistor beneath caused by the etching mask distortion when the memory transistor is formed over the select transistor.

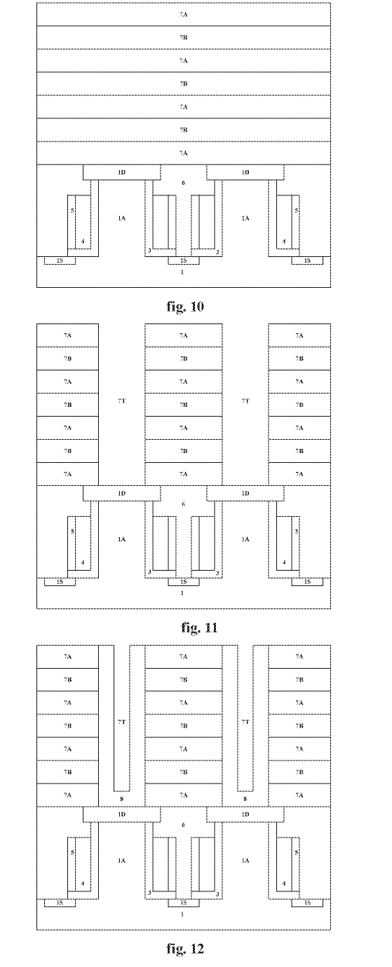

As shown in FIG. 10, a stack structure 7 composed of a plurality of first material layers 7A and second material layers 7B alternately formed throughout the device (i.e., on top of the drain regions 1D and ILD6) is formed. The material of the stack structure 7 is selected from combination of the following material and comprises at least one insulating dielectric: e.g. silicon oxide, silicon nitride, amorphous carbon, amorphous diamond-like carbon (DLC), germanium oxide, aluminum oxide, or the like and combinations thereof. The first material layers 7A have a first etch selectivity, and the second material layers 7B have a second etch selectivity which is different from the first etch selectivity. In one preferred embodiment of the invention, laminate structure 7A/7B are both insulating material, and the combination of layers 7A/7B is a combination of silicon oxide and silicon nitride, a combination of silicon oxide and polycrystalline silicon or amorphous silicon, a combination of silicon oxide and silicon nitride or amorphous carbon and the like, for example. In another preferred embodiment of the invention, the layers 7A have a relatively greater etching selectivity ratio to layers 7B (for example greater than 5:1) at wet etching conditions or oxygen plasma dry etching conditions. The method for depositing layer 7A, 7B comprises PECVD, LPCVD, HDPCVD, MOCVD, MBE, ALD, thermal oxidation, evaporation, sputtering, and other processes. As shown in FIG. 11, the stack structure 7 is etched through till the substrate drain regions 1D are exposed, forming a plurality of trenches 7T vertically punching through the stack structure and used to define the vertical channel regions of the memory transistor string. Preferably, the stack structure 7 of layers 7A/7B is anisotropically etched by RIE or plasma dry etching, exposing the substrate drain regions 1D and the sidewalls of layers 7A/7B alternately stacked thereon. More preferably, the process conditions of anisotropic etching of stack structure are controlled in order to make the lateral etching rate being significantly less than the longitudinal etching rate, obtaining a plurality of vertical deep holes or deep trenches 7T with high aspect ratio (e.g., aspect ratio AR being greater than or equal to 10:1). The cross-sectional shape of trenches 7TP obtained by cutting parallel to the surface of substrate 1 may be various geometric shapes selected from rectangular, square, diamond, circular, semi-circular, elliptical, triangular, pentagonal, hexagonal, octagonal, etc.

As shown in FIG. 12, a plurality of vertical channel layers 8 are formed in the trenches 7T. The materials of the channel layers 8 include monocrystalline silicon, amorphous silicon, polycrystalline silicon, microcrystalline silicon, monocrystalline germanium, SiGe, Si:C, SiGe:C, SiGe:H and other semiconductor materials, formed by the deposition process described above. In one embodiment of the present invention shown in FIG. 12, the deposition process of channel layers 8 is partially filling the sidewalls of trenches 7T to form hollow cylinders with air gaps. In other embodiments of the present invention not shown, the deposition process of channel layers 8 is chosen to completely or partially fill the trenches 7T, thereby forming a plurality of solid columns, hollow rings, or core-shell structures having hollow rings with filled insulating layer (not shown). The shape of the horizontal cross section of channel layers 8 is similar and preferably conformal to those of trenches 7T, and can be various solid geometric shapes, such as rectangle, square, diamond, circular, semi-circular, elliptical, triangular, pentagonal, hexagonal shaped, octagonal etc., or annular or tubular hollow structures evolved from geometric shapes described above (and its interior may be filled with insulating layers). The bottom part of vertical channel layers 8 are used as the source 8S of the memory cell transistor.

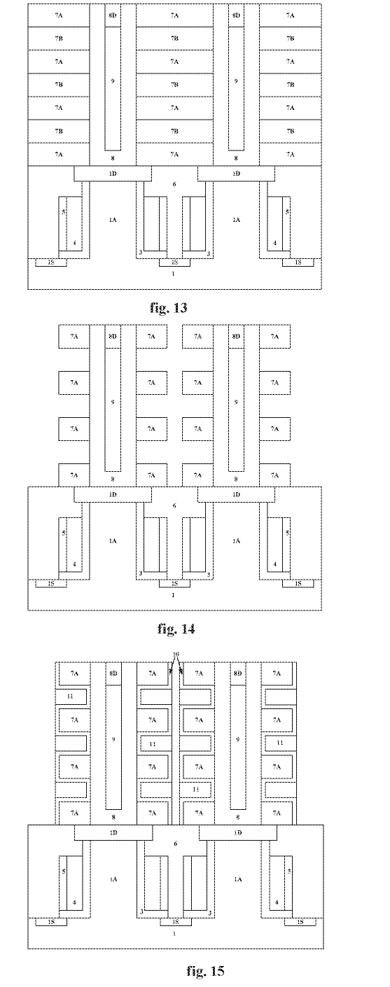

As shown in FIG. 13, the drain regions of memory strings 8D are formed. Preferably, for the structure of hollow pillar-shaped channel layers 8, it can be further filled with an plurality of insulating spacer layer 9 inside the channel layers 8, for example, layers 9 made of silicon oxide can be formed through process such as LPCVD, PECVD, HDPCVD, etc., used for supporting, insulating and isolating the channel layers 8. Thereafter, drain regions 8D are deposited on top of the channel layers 8. Preferably, the drain regions 8D of memory device cell transistors are formed by depositing materials as the same or similar to those of channel layers 8 (e.g., materials similar to Si, such as SiGe, SIC, etc., in order to fine-tune the lattice constants and improve the carrier mobility, thereby controlling the driving performance of cell components) on top of trenches 7T. Naturally, if it is different from those shown in FIG. 13 that the channel layers 8 are solid structures filled completely, then the portions of channel layers 8 on the top of whole device constitute the corresponding drain regions 8D without additional drain region deposition step.

As shown in FIG. 14, the second material layers 7B are removed by selective etching until the select transistors are exposed (in particular, exposing ILD6 and the drains 1D), leaving the discrete vertical structures constituted of the first material layers 7A, the channel layers 8 and the insulating spacer layers 9 on the ILD6 of the select transistors. Depending on the difference between material of layers 7A and layers 7B, wet etching solution is chosen for removing the layers 7B by isotropic etching. Specifically, for different materials of the layers 7B, the HF-based etchant is utilized for silicon oxide material, hot phosphoric acid etchant is used for silicon nitride material, or strongly alkaline etchant such as KOH or TMAH is used for polycrystalline silicon or amorphous silicon material. In addition, oxygen plasma dry etching can be chosen for carbon-based materials such as amorphous carbon or DLC, making O and C react to form gases to be exhausted. Furthermore, using anisotropic dry etching process such as plasma dry etching, RIE, etc., the residual first material layers 7A along the word line (WL) extending direction is etched, in order to form the string structure along the WL direction. After removing the layers 7B, a plurality of horizontal recesses (in the horizontal direction parallel to the substrate surface) are formed between the first material layers 7A, used for the subsequent formation of a control electrode. To be noted that, in one embodiment of the present invention, as shown in FIG. 14, in order to remove the horizontal layers 7B more effectively through selective etching, the first step can be forming a plurality of vertical openings or trenches exposing ILD6 (not marked in figures) by anisotropic etching process, followed by laterally etching started from the sidewalls of the vertical openings or trenches in order to completely remove the horizontal layers 7B. As shown in FIG. 15, a plurality of stack structures 10 composed of memory transistor gate dielectric layers are formed in the horizontal recesses. Deposition methods include PECVD, HDPCVD, MOCVD, MBE, ALD, evaporation, sputtering or the like. It is not shown in figures that the each layer 10 preferably further comprises a plurality of sub-layers, such as a tunneling layer, a storage layer, a barrier layer. Wherein the tunneling layers compose SiO2 or high-k material, and the high-k materials include, but are not limited to nitride (such as SiN, AlN, TiN), metal oxides (mainly subgroup and lanthanide metal element oxides, such as MgO, Al2O3, Ta2O5, TiO₂, ZnO, ZrO₂, HfO2, CeO2, Y2O3, La2O3), nitrogen oxides (e.g., HfSiON), perovskite phase oxide (e.g. PbZrxTi1-xO3(PZT) BaxSr1-xTiO3(BST)), etc., and tunneling layer may be monolayer or multilayer stacked structure of the above materials. The storage layer is dielectric material with charge trapping capabilities, e.g., SiN, HfO, ZrO, etc., and combinations thereof, also may be the monolayer structure or multilayer stacked structure of the above materials. The barrier layer may be monolayer or multilayer stacked structure made of dielectric materials such as silicon oxide, aluminum oxide, hafnium oxide and the others. In one embodiment of the invention, the stack structures 10 of the gate dielectric layers, for example, can be the ONO structure composed of silicon oxide, silicon nitride and silicon oxide. Then, a gate conductive layer 11 is formed by deposition filling. The gate conductive layers 11 may be polysilicon, a polycrystalline silicon-germanium, or metals, wherein the metals may comprise metal elements such as Co, Ni, Cu, Al, Pd, Pt, Ru, Re, Mo, Ta, Ti, Hf, Zr, W, Ir, Eu, Nd, Er, La and the others, or alloys of these metals and the nitrides of these metals, and gate conductive layers 11 may also be doped with C, F, N, O, B, P, As and other elements to adjust the work function. Nitride barrier layers (not shown) are preferably formed between the gate dielectric layers 10 and gate conductive layers 11 by PVD, CVD, ALD and other conventional processes, the material of barrier layer is MxNy, MxSiyNz, MxAlyNz, MaAlxSiyNz, wherein the M is Ta, Ti, Hf, Zr, Mo, W, or other elements. Likewise, layers 11 may be a monolayer structure, or also be a multilayer stacked structure. In this case, the first material layers 7A above or below a plurality of gate conductive layers 11 are insulating dielectric materials, thus they are constituting the insulating spacer layers between the gate conductive layers 11.

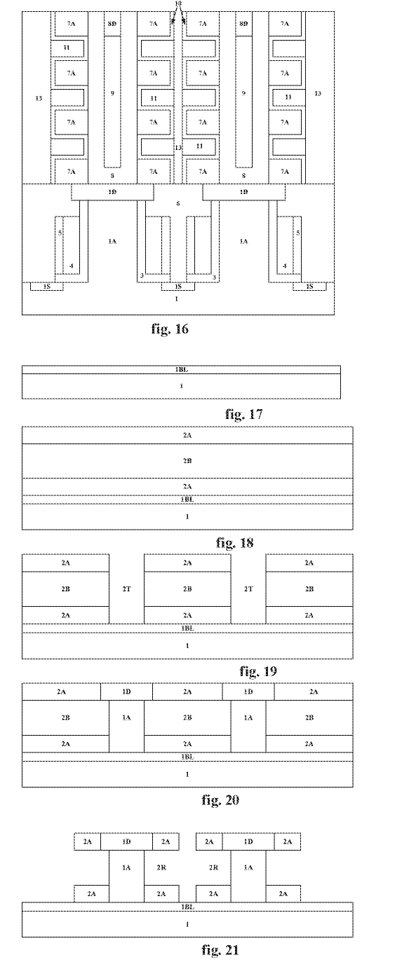

As shown in FIG. 16, a second interlayer dielectric layer (ILD) 13 is formed on the entire device. The formation process and materials of ILD13 are similar to that of ILD6. Preferably, ILD13 is planarized using processes such as CMP, etch-back, etc., until the first material layers 7A are exposed.

In addition, an upper the select transistor (not shown) above the vertical channel 8 of the memory strings may be formed using the methods as shown in FIG. 1 to FIG. 9, in order to create the BiCS structure. However, according to the procedures of the first embodiment of the present invention, the three-dimensional device structure is formed as shown in FIG. 16, comprising a plurality of memory cell transistors and a plurality of select transistors at least partially overlapped in the vertical direction, wherein each select transistor comprises a first drain 1D, an active region 1A (including the first channel layer next to the sides of the metal gate 4), a common source 1S, which are distributed along the vertical direction, also comprises the metal gate 4 distributed around the active region, the metal gate 4 may be multi-gate structure (preferably symmetrically distributed), or annular gate structure; each memory cell transistor comprises a channel layer 8 distributed perpendicularly to the substrate surface, a plurality of inter-layer insulating layers 7A and a plurality of gate stack structure 10/11 alternately stacked along the sidewalls of the channel layer 8, the second drain 8D is located on top of the channel layer 8. Wherein the gate stack structure includes a gate dielectric layer 10 and a gate conductive layer 11, the gate dielectric layer 10 further comprises a tunneling layer, a storage layer and a barrier layer, the bottom and sidewalls of the gate conductive layer 11 are surrounded by the gate dielectric layer 10. Other specific arrangements, material characteristics and formation process are as described above. FIGS. 17 to 24 are cross-sectional views of the various steps of the methods of forming multi-gate select transistor based on the gate-last process and forming memory transistor string thereon in accordance with the second embodiment of the present invention; As shown in FIG. 17, a substrate 1 is provided as described above. Preferably, a bit-line 1BL is formed on the said substrate 1, through an ion implantation process, such as n+ doped type, a highly-doped low resistance bit-line 1BL can be formed. The bit-line 1BL plays the role of the common sources 1S as shown in FIG. 1 to FIG. 16.

As shown in FIG. 18, stack structure 2 composed of the plurality of first mask layers 2A and the second mask layers 2B are alternately formed on substrate 1. The material of the stack structure 2 is selected from combination of the following material and comprises at least one insulating dielectric: e.g. silicon oxide, silicon nitride, amorphous carbon, amorphous diamond-like carbon (DLC), germanium oxide, aluminum oxide, or the like and combinations thereof. The first mask layers 2A have a first etch selectivity, and the second mask layers 2B have a second etch selectivity which is different from the first etch selectivity. In one preferred embodiment of the invention, laminated structure 2A/2B are both insulating material, and the combination of layers 2A/2B is a combination of silicon oxide and silicon nitride, a combination of silicon oxide and polycrystalline silicon or amorphous silicon, a combination of silicon oxide and silicon nitride or amorphous carbon and the like, for example. In another preferred embodiment of the invention, the layers 2A have a relatively greater etching selectivity ratio (for example greater than 5:1) to the layers 2B at wet etching conditions or oxygen plasma dry etching conditions. The method for depositing layers 2A, 2B comprises PECVD, LPCVD, HDPCVD, MOCVD, MBE, ALD, thermal oxidation, evaporation, sputtering, and other processes. In a preferred embodiment of the invention, there are two layers 2A and one layers 2B, and the thickness of each layer 2B is greater than that of layer 2A (e.g., the thickness of each layer 2B is greater than or equal to 2 times the thickness of the layer 2A, and 10-100 nm is preferred).

As shown in FIG. 19, the stacked structure 2 is etched, forming a plurality of through-holes 2T to expose substrate 1 (1BL on the surface of substrate 1). Anisotropic dry etching is preferred, for example, using plasma dry etching or RIE with the fluorocarbon-based etching gases.

As shown in FIG. 20, the active regions 1A of the said select transistors are formed in the through-holes 2T. For example, using epitaxial deposition or CVD deposition method, the active regions 1A with the material as same as or similar to substrate 1, e.g., monocrystalline or polycrystalline Si, are formed. Further preferably, similar to FIGS. 8 and 9, the top width of each of the through-holes 2T can be enlarged to form wider drain 1D.

As shown in FIG. 21, the second mask layers 2B are removed by selective etching, leaving lateral recess 2R between the first mask layers 2A. Wet etching can be used, for example, using hot phosphoric acid for silicon nitride material, or HF-based etching solution for silicon oxide material; or may be isotropic dry etching, for example, oxygen plasma etching for layers 2B made of amorphous carbon material. Then, regions used for defining the word lines are etched, therefore the transverse width of the residual layers 2A is limited by etching.

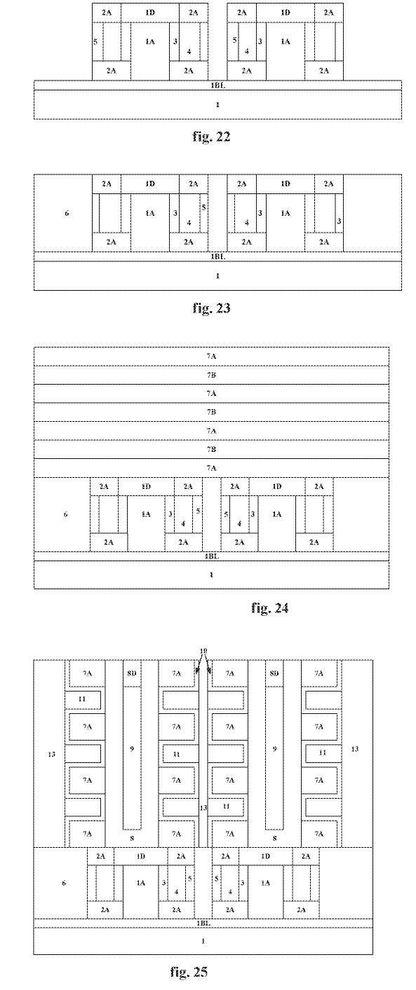

As shown in FIG. 22, the lateral recesses 2R are filled to form the gate insulating layers 3 and the metal gates 4 of select transistors, as well as the optional gate sidewalls 5. The materials and processes of layers 3 and 4 are as described in embodiment 1. Preferably, etch-back process or anisotropic vertical-etching is performed, till the sidewalls of layers 2A are exposed. Similar to FIG. 6, the metal gates 4 are also a dual-gate or multi-gate surrounded structure.

As shown in FIG. 23, similar to FIG. 9, ILD layer 6 similar to embodiment 1 is deposited over the entire device, and preferably planarized to expose the drain 1D.

As shown in FIG. 24, similar to FIG. 10, the stack structure 7 composed of the plurality of first material layers 7A and the second material layers 7B is deposited over the entire device, so as to form a subsequent BiCS structure. The subsequent steps are similar to those shown in FIG. 11 to FIG. 16, no further explanation here.

As shown in FIG. 25, in the final device structure, similar to FIG. 16, the three-dimensional device structure is formed as shown in FIG. 16, comprising a plurality of memory cell transistors and a plurality of select transistors at least partially overlapped in the vertical direction, wherein each select transistor comprises a first drain 1D, an active region 1A (including the first channel layer next to the sides of the metal gate 4), a common source 1S, which are distributed along the vertical direction, also comprises the metal gate 4 distributed around the active region, the metal gate 4 may be multi-gate structure (preferably symmetrically distributed), or annular gate structure; each memory cell transistor comprises a channel layer 8 distributed perpendicularly to the substrate surface, a plurality of inter-layer insulating layers 7A and a plurality of gate stack structure 10/11 alternately stacked along the sidewalls of the channel layer 8, the second drain 8D is located on top of the channel layer 8. Wherein the gate stack structure includes a gate dielectric layer 10 and a gate conductive layer 11, the gate dielectric layer 10 further comprises a tunneling layer, a storage layer and a barrier layer, the bottom and sidewalls of the gate conductive layer 11 are surrounded by the gate dielectric layer 10. Other specific arrangements, material characteristics and formation process are as described above.

In accordance with the three-dimensional semiconductor memory device and manufacturing method of the present invention, the multi-gate MOSFET is formed beneath the stack structure of the memory cell string including vertical channel to serve as the select transistor, this can improve the control characteristics of the gate threshold voltage, reduce the off-state leakage current, prevent the substrate from over-etching, and effectively improve the reliability of the device.

Although the present invention is descried with one or more exemplary embodiments, one skilled in the art will recognize that various appropriate changes and equivalents of the device structures can be made without departing from the scope of the present invention. Furthermore, a great deal of modifications of specific situation or materials can be made to the disclosed enlightenment without departing from the scope of the present invention. Thus, the intent of the present invention is not limited to the disclosed illustrative examples for implementing the best embodiments. The disclosed device structures and the method of manufacturing the same will include all the exemplary embodiments within the scope of the invention.

What is claimed is that:

1. A three-dimensional semiconductor device, comprising a plurality of memory cell transistors and a plurality of select transistors at least partially overlapped in the vertical direction,
wherein each select transistor comprises a first drain, an active region and a common source formed in the substrate, distributed along the vertical direction, as well as a metal gate distributed around the active region;
wherein each memory cell transistor comprises a channel layer distributed perpendicularly to the substrate surface, a plurality of inter-layer insulating layers and a plurality of gate stack structures alternately stacked along the sidewalls of said channel layer, a second drain located on top of said channel layer;
wherein said channel layer and said the first drain are electrically connected.

2. The three-dimensional semiconductor device of claim 1, wherein, said metal gate is multi-gate structure or annular gate structure.

3. The three-dimensional semiconductor device of claim 1, wherein, the transverse dimension of said first drain is greater than or equal to that of said channel layer.

4. The three-dimensional semiconductor device of claim 1, wherein, each select transistor includes a gate insulating layer, said gate insulating layer surrounds the bottom and sidewalls of said metal gate.

5. The three-dimensional semiconductor device of claim 1, wherein, each of the plurality of gate stack structures comprises a gate dielectric layer composed of a tunneling layer, a storage layer and a barrier layer.

6. A method of manufacturing a three-dimensional semiconductor device, comprising the steps of:
forming an active region of the select transistor on a substrate;
forming a metal gate of select transistor around the active region;
forming a stack structure of a plurality of first material layers and the second material layers on the select transistor;
etching the stack structure to form a plurality of vertical trenches;
forming a channel layer of a memory cell transistor in each trench;
selectively removing the second material layers, leaving a plurality of lateral recesses between the first material layers;
forming a plurality of gate stack structures in the plurality of lateral recesses.

7. The method of claim 6, wherein, the steps of forming the active region comprise:
a) etching the substrate to form a plurality of vertically distributed active region; or
b) forming a mask stack structure composed of a first mask layers and a second mask layers on the substrate, etching the mask stack structure to form a plurality of through-holes, forming the active regions by deposition in the through-holes.

8. The method of claim 7, wherein, further comprises the step of:
a1) After forming a metal gate, forming an inter-layer dielectric layer on the substrate, etching the inter-layer dielectric layer to form an opening exposing the active region, forming a first drain in the opening; or
b1) before forming a metal gate, forming an opening exposing the active region on top of the mask stack structure, forming a first drain in the opening.

9. The method of claim 8, wherein, the transverse dimension of said first drain is greater than or equal to that of said openings exposing the active regions.

10. The method of claim 6, wherein, each of the plurality of gate stack structure comprises a gate dielectric layer composed of a tunneling layer, a storage layer and a barrier layer.
